(19) United States
(12) Patent Application Publication
(10) Pub. No.: US 2026/0319054 A1
(43) Pub. Date: Oct. 15, 2026

(54) SEMICONDUCTOR INSPECTION SYSTEM AND CALIBRATION METHOD FOR OPERATING THE SAME

(71) Applicant: TAIWAN SEMICONDUCTOR MANUFACTURING COMPANY LTD., HSINCHU (TW)

(72) Inventors: YING-CHIH HSU, HSINCHU CITY (TW); MU WEI LEE, TAIPEI CITY (TW); JUI-CHENG HUANG, HSINCHU CITY (TW); WEI-TAO SHAW, HSINCHU CITY (TW)

(21) Appl. No.: 19/173,855

(22) Filed: Apr. 9, 2025

(51) Int. Cl. G01R 35/00; G01R 1/073; G01R 31/28

(52) U.S. Cl. CPC G01R 35/005; G01R 1/07342; G01R 31/2886

(57) ABSTRACT

A semiconductor inspection system and a calibration method are provided. The semiconductor inspection system comprises a probe card device, a calibration device and a testing device. The probe card device is configured to perform a first measurement on a semiconductor device. The probe card device is disposed on a first printed circuit board (PCB). The calibration device is electrically connected to the probe card device and is configured to execute a second measurement to obtain a plurality of impedance values of the probe card device in order to calibrate the probe card device. The calibration device is disposed on a second PCB different from the first PCB. The second PCB is provided on a chuck plate, and the second measurement is executed before the first measurement. The testing device is electrically connected to the calibration device and is configured to analyze the plurality of impedance values of the second measurement.

### BACKGROUND

The present disclosure relates, in general, to a semiconductor inspection system and calibration methods for operating the same. Specifically, the present disclosure relates to a semiconductor inspection system and calibration methods utilizing a calibration device.

Various semiconductor inspection system have been widely used for a wide range of applications, such as monitoring the characteristics or performance of a semiconductor devices. However, the parasitic effects of these semiconductor inspection systems can degrade the measurement accuracy of the semiconductor device.

### BRIEF DESCRIPTION OF THE DRAWINGS

Aspects of the embodiments of the present disclosure are best understood from the following detailed description when read with the accompanying figures. It should be noted that, in accordance with standard practice in the industry, various structures are not drawn to scale. In fact, the dimensions of the various structures can be arbitrarily increased or reduced for clarity of discussion.

FIG. 1A is a schematic view of a semiconductor inspection system for measuring a semiconductor device, in accordance with some embodiments of the present disclosure.

FIG. 1B is a top view of a semiconductor device, in accordance with some embodiments of the present disclosure.

FIG. 2 is a schematic view of the semiconductor inspection system, in accordance with some embodiments of the present disclosure.

FIG. 3 is a perspective view of the semiconductor inspection system, in accordance with some embodiments of the present disclosure.

FIG. 4A is a top view of a calibration device, in accordance with some embodiments of the present disclosure.

FIG. 4B illustrates a cross-section view of the calibration device along the section line CS1 in FIG. 4A, in accordance with some embodiments of the present disclosure.

FIG. 4C illustrates a cross-section view of the calibration device along the section line CS2 in FIG. 4A, in accordance with some embodiments of the present disclosure.

FIG. 5A is a top view of a calibration device, in accordance with some embodiments of the present disclosure.

FIG. 5B illustrates a cross-section view of the calibration device along the section line CS3 in FIG. 5A, in accordance with some embodiments of the present disclosure.

FIG. 5C illustrates a cross-section view of the calibration device along the section line CS4 in FIG. 5A, in accordance with some embodiments of the present disclosure.

FIG. 6A is a perspective view of the semiconductor inspection system, in accordance with some embodiments of the present disclosure.

FIG. 6B is a circuit diagram corresponding to the semiconductor inspection system of FIG. 6A, in accordance with some embodiments of the present disclosure.

FIG. 7A is a perspective view of the semiconductor inspection system, in accordance with some embodiments of the present disclosure.

FIG. 7B is a circuit diagram corresponding to the semiconductor inspection system of FIG. 7A, in accordance with some embodiments of the present disclosure.

FIG. 8A is a circuit diagram corresponding to the calibration device, in accordance with some embodiments of the present disclosure.

FIG. 8B is another circuit diagram corresponding to the calibration device in accordance with some embodiments of the present disclosure.

FIG. 9A illustrates a flow chart including calibration methods for operating the semiconductor inspection system, in accordance with some embodiments of the present disclosure.

FIG. 9B illustrates another flow chart including calibration methods for operating the semiconductor inspection system, in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

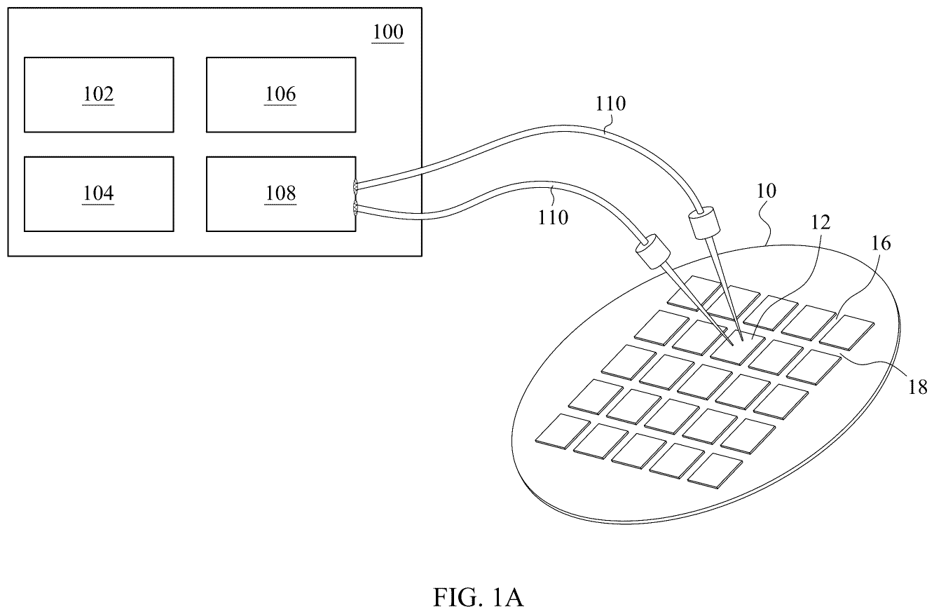

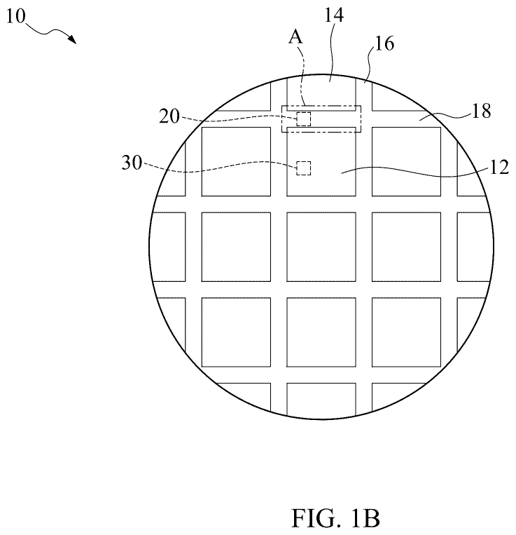

FIG. 1A is a schematic view of a semiconductor inspection system 100 for measuring a semiconductor device 10, in accordance with some embodiments of the present disclosure. FIG. 1A shows a semiconductor inspection system 100 for testing/measuring a semiconductor device 10. The semiconductor device 10 can also include a semiconductor wafer on which a semiconductor die to be tested/measured can be included.

The semiconductor device 10 can comprise an elementary semiconductor such as silicon, germanium, or diamond. The semiconductor device 10 may include one or more dies 12 formed thereon. A plurality of scribe lines 16 and 18 can be provided between adjacent dies 12 so that dies 12 can be separated/singulated in subsequent processing. In some embodiments, the dies 12 can be integrated circuits (ICs) or chips. The semiconductor device 10 may include a plurality of dies 12 and several process control monitoring (PCM) devices (not shown in FIG. 1A). A PCM device can be regarded as a PCM device that can be utilized to evaluate the characteristics/performance of the dies 12.

A PCM device may include one or more basic components that are utilized to constitute the circuits within the dies 12. Therefore, the characteristics/performance of the circuits within the dies 12 can be evaluated after the characteristics/performance of the one or more basic components are obtained. The PCM devices can be used to monitor the characteristics of the dies 12 during a wafer acceptance test (WAT). The PCM device can be formed in a scribe line, a street, or other locations not occupied by the circuits within the dies 12 on the semiconductor device 10.

Referring to FIG. 1A, the semiconductor inspection system 100 can be test/measurement equipment. The semiconductor inspection system 100 may include hardware and software components that provide a suitable operational and/or functional environment for the dies 12 to be tested. In some embodiments, the semiconductor inspection system 100 may include a processor 102, a signal generator 104, a monitor 106, and a coupler 108.

Signals/commands can be transmitted between each of the processor 102, the signal generator 104, the monitor 106, and the coupler 108. In some embodiments, the signals transmitted within the semiconductor inspection system 100 can include power signals having adjustable voltage levels.

In various embodiments, the processor 102 may include, but is not limited to, at least one hardware processor, including at least one microprocessor such as a CPU, a portion of at least one hardware processor, or any other suitable dedicated processor such as those developed based on Field Programmable Gate Array (FPGA) and Application Specific Integrated Circuit (ASIC).

The signal generator 104 is configured to provide test signals. All types of electrical signals, such as data signals, clock signals, or power signals, can be provided to a PCM device associated with the die 12. In some embodiments, electrical signals can also be provided to the die 12 directly.

The monitor 106 is configured to determine whether the PCM device complies with a test criterion. The signals fed back from the PCM device can be evaluated by the monitor 106, and a determination can be made as to whether the PCM device complies with the test criterion. The monitor 106 can provide/display information and/or instructions to the user. In some embodiments, the monitor 106 can display pop-up notifications. In some embodiments, the monitor 106 can provide alarm messages to the user when the PCM device fails to comply with certain test criteria.

The coupler 108 is configured to couple the signal generator 104 to the PCM device on the semiconductor device 10. In some embodiments, the coupler 108 can be coupled to the PCM device by one or more probes 110. The probes 110 can be part of a probe head or probe package (not shown). The probes 110 can be electrically coupled to test conductive contacts (pads) and/or bonding pads disposed on the PCM devices. The test conductive pads and/or bonding pads provide electrical connections to an interconnect structure (e.g., wiring) of the dies. For example, some of the probes 110 can be coupled to pads that are associated with a supply terminal (e.g., Vdd) and ground terminal (e.g., Vss) of the PCM device. Other probes can be coupled to pads associated with input/output (I/O) terminals (e.g., data signals) of the PCM device. As such, the semiconductor inspection system 100 is operable to apply electrical signals to the PCM device and obtain response/feedback signals from the PCM device during WAT.

FIG. 1B is a top view of a semiconductor device 10, in accordance with some embodiments of the present disclosure. FIG. 1B shows a top view of an example semiconductor device 10.

Referring to FIG. 1B, the semiconductor device 10 may include a plurality of dies (such as dies 12 and 14) arranged in a grid pattern, which includes a plurality of rows and columns of dies. Each column of dies or chips are separated by vertical scribe lines 16, and each row of the dies is separated by horizontal scribe lines 18.

Individual dies 12 and 14 within the semiconductor device 10 may contain circuitry. The dies 12 and 14 can be separated by a sawing operation performed through the scribe line (e.g., the horizontal scribe line 18) and then packaged to form individual devices. The dies 12 and 14 on the semiconductor device 10 may include several basic circuit components (e.g., basic circuit component 30), which can be interconnected to form a semiconductor device having logical or other functions. In some embodiments, the basic circuit components may include active devices such as transistors, and passive devices such as resistors, capacitors, inductors, or a combination thereof.

In an exemplary semiconductor fabrication process, each basic circuit component may need to be tested and/or evaluated at selected stages of the fabrication process, so as to assure the device quality. However, an individual basic circuit component (e.g., basic circuit component 30) may not be readily testable once integrated into a circuit. In order to verify that each basic circuit component was fabricated according to design specification and exhibits selected properties or values, the PCM devices (e.g., benchmark device 20) can be used as an applicable quality control methodology.

A benchmark device 20 can also be referred to as a device-under-test (DUT) device throughout the present disclosure. Referring to FIG. 1B, the dotted rectangle A can be the location within which the DUT devices can be located. The areas containing the DUT devices can be referred to as a PCM test line or abbreviated as a test line throughout the present disclosure.

A DUT device can include various basic circuit components fabricated together with the circuits within the dies 12. Such DUT device (e.g., benchmark device 20) may have properties similar to their counterparts (e.g., basic circuit component 30) in the dies 12, since they are fabricated using the same process. As such, the electrical characteristics (such as, but not limited to, a test result, response to signal, performance parameter, etc.) of the circuits within the dies 12 can be appropriately evaluated after the electrical characteristics of the DUT device are obtained. Each DUT device can be coupled to the signal generator 104 through one or more conductive pads exposed on the semiconductor device 10.

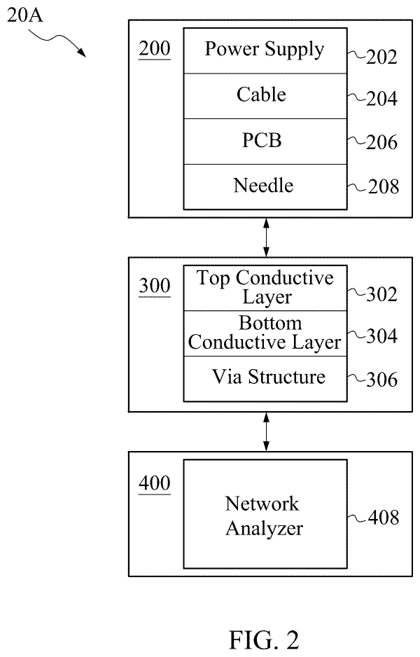

FIG. 2 is a schematic view of the semiconductor inspection system 20A, in accordance with some embodiments of the present disclosure. The semiconductor inspection system 20A of FIG. 2 can be similar to the semiconductor inspection system 100 of FIG. 1A, except for the differences described as follows. The semiconductor inspection system 20A includes a probe card device 200, a calibration device 300, and a testing device 400. The probe card device 200 can be electrically connected to the calibration device 300, and the calibration device 300 can be electrically connected to the testing device 400.

The probe card device 200 at least includes a power supply 202, a cable 204, a printed circuit board (PCB) 206, and a needle 208. The probe card device 200 is configured to perform a measurement on the semiconductor device 10 by directly touching the semiconductor device 10 through the needle 208. The power supply 202 can provide electrical power to the probe card device 202. The power supply 202 can be electrically connected to an external power source or a battery. The cable 204 is electrically connected between the power supply 202 and the PCB 206. The probe card device 200 can be disposed on the PCB 206. The probe card device 200 can include a plurality of needles 208. The needles 208 are electrically connected to the power supply 206. The needles 208 of FIG. 2 can correspond to or be included in the probes 110 of FIG. 1A. The needles 208 are configured to be in direct contact with the semiconductor device 10 to perform a measurement.

The calibration device 300 at least includes a top conductive layer 302, a bottom conductive layer 304, and a via structure 306. The top conductive layer 302 is formed above the bottom conductive layer 304. The calibration device 300 can include several via structures 306. The via structures 306 can be formed between the top conductive layer 302 and the bottom conductive layer 304. The top conductive layer 302 can be electrically connected to the bottom conductive layer 304 through the via structures 306. In some embodiments, the calibration device 300 is electrically connected to the probe card device 200. The calibration device 300 is configured to execute a measurement to obtain a plurality of impedance values of the probe card device 200 in order to calibrate the probe card device 200. The impedance values can include at least one parasitic inductance value and at least one parasitic capacitance value of the probe card device 200.

The testing device 400 can include a network analyzer 408. The testing device 400 can be electrically connected to the calibration device 300. The network analyzer 408 of the testing device 400 is configured to analyze the impedance values obtained from the measurement on the calibration device 300. The network analyzer 408 of FIG. 2 can correspond to or include the processor 102 of FIG. 1A.

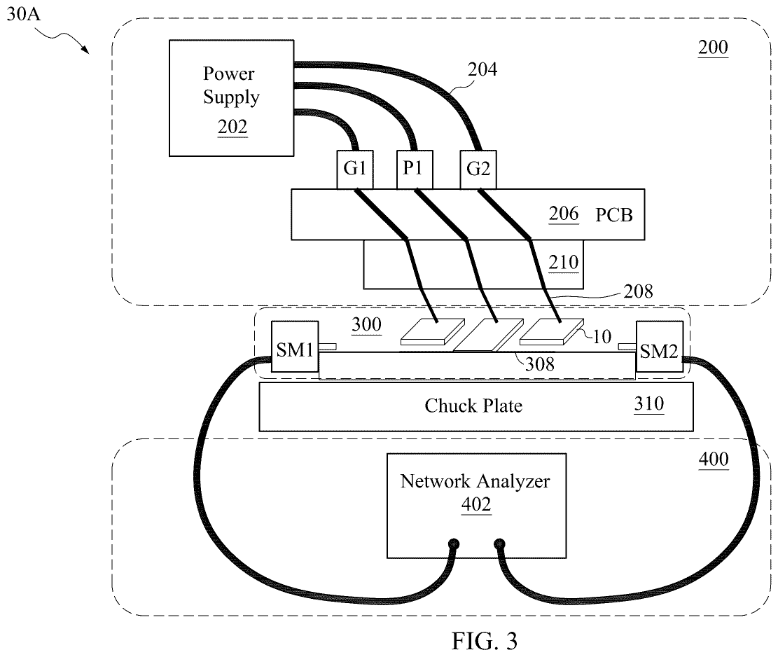

FIG. 3 is a perspective view of the semiconductor inspection system 30A, in accordance with some embodiments of the present disclosure. The semiconductor inspection system 30A of FIG. 3 can be similar to the semiconductor inspection system 20A of FIG. 2, except for the differences described as follows.

The semiconductor inspection system 30A includes a power pin P1 and two ground pins G1 and G2. The power pin P1 is electrically connected to one of the needles 208 to transmit power from the power supply 202 to the semiconductor device 10. The semiconductor device 10 can be included in the calibration device 300. The ground pins G1 and G2 are electrically connected to the needles 208 and the power supply 202 to serve as a ground of the semiconductor inspection system 30A. The cables 204 are electrically connected between the power supply 202 and the power pin P1 and ground pins G1 and G2. The power pin P1 and ground pins G1 and G2 can be disposed on the PCB 206. The needles 208 can be surrounded by and penetrate the PCB 206 to contact the semiconductor device 10. In some embodiments, the probe card device 200 can further include a probe head 210 to accommodate or hold the needles 208. The probe head 210 can be adjacent to or below the PCB 206. The needles 208 can pass through the PCB 206 and the probe head 210. The needles 208 can protrude from the bottom surface of the probe head 210 to be in contact with the semiconductor device 10 for measurement.

The calibration device 300 can further include two connectors SM1 and SM2 for electrically connecting the calibration device 300 to the testing device 400. Each of the connectors SM1 and SM2 can include an SMA connector. In some embodiments, the two connectors SM1 and SM2 are provided on opposite ends of the calibration device 300. The two connectors SM1 and SM2 can be electrically connected to the network analyzer 402 through wires or cables for transmitting electrical signals. Accordingly, the network analyzer 402 can evaluate and analyze the impedance values obtained from the calibration device 300.

The calibration device 300 can be disposed on the PCB 308, which is different from and separated apart from the PCB 206. In some embodiments, the PCB 308 can be disposed on the chuck plate 310. The chuck plate 310 can be used to uphold the calibration device 300 and the semiconductor device 10 for improving a stable measuring environment. The chuck plate 310 may include, for example, aluminum (Al), copper (Cu), chromium (Cr), tin (Sn), gold (Au), silver (Ag), nickel (Ni) or stainless steel, another metal, or a mixture, an alloy, or other combinations of two of more thereof.

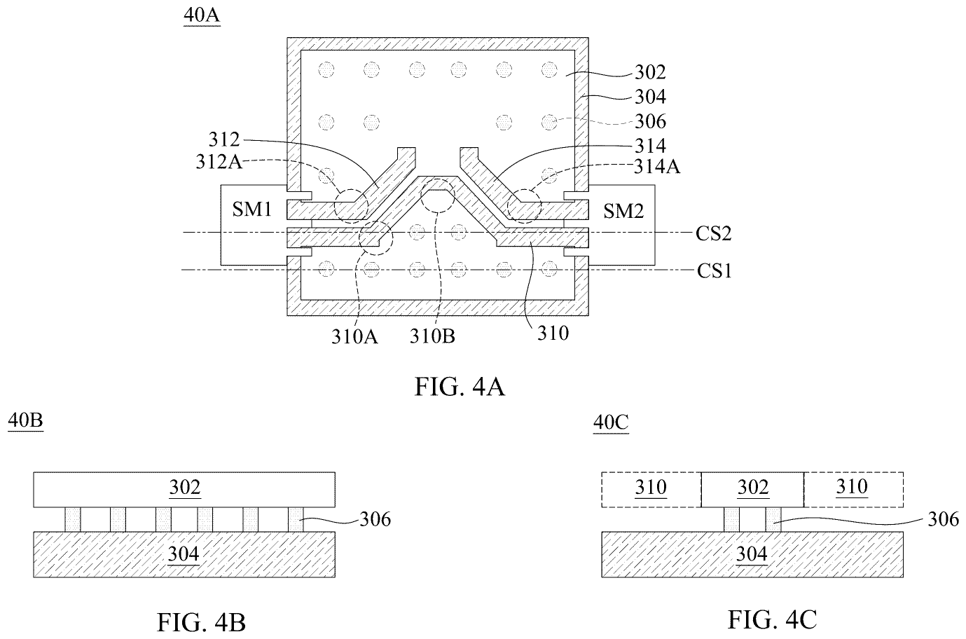

FIG. 4A is a top view of a calibration device 40A, in accordance with some embodiments of the present disclosure. The calibration device 40A of FIG. 4A can be similar to the calibration device 300 of FIG. 2 and FIG. 3, except for the differences described as follows.

The calibration device 40A includes a top conductive layer 302, a bottom conductive layer 304, several via structures 306, and two connectors SM1 and SM2. As shown in FIG. 4A, the bottom conductive layer 304 is electrically connected between the two connectors SM1 and SM2. The bottom conductive layer 304 can be in a rectangular shape from the top view of the calibration device 40A. The top conductive layer 302 is formed above the bottom conductive layer 304. The top conductive layer 302 is electrically connected between the two connectors SM1 and SM2. The top conductive layer 302 can be in a rectangular shape from the top view of the calibration device 40A. Each of the top conductive layer 302 and the bottom conductive layer 304 can be a conductive thin film, and may include, for example, aluminum (Al), copper (Cu), chromium (Cr), tin (Sn), gold (Au), silver (Ag), nickel (Ni) or stainless steel, or a mixture, an alloy, or other combinations thereof. Each of the top conductive layer 302 and the bottom conductive layer 304 may include a single conductive layer or multiple conductive layers. The top conductive layer 302 and the bottom conductive layer 304 can be made of the same material. The top conductive layer 302 and the bottom conductive layer 304 can be made of different materials.

In some embodiments, the rectangular shape of the top conductive layer 302 can overlap with the rectangular shape of the bottom conductive layer 304. The rectangular shape of the top conductive layer 302 can be formed within the rectangular shape of the bottom conductive layer 304. As shown in FIG. 4A, a portion of the top conductive layer 302 is removed to expose the bottom conductive layer 304 to provide a winding path 310 with a plurality of corners 310A and 310B. The winding path 310 can be connected to two connectors SM1 and SM2 at its two ends. The winding path 310 can be in a tortuous shape with several twists or turning points, such as the corners 310A and 310B. The inclination angle of the corner 310A can be substantially identical to that of the corner 310B. The inclination angle of the corners 310A and 310B can be around 135 degrees. Forming the winding path 310 can include performing one or more lithography, deposition, etching, planarizing, or other suitable processes.

In some embodiments, a portion of the top conductive layer 302 is removed to expose the bottom conductive layer 304 to provide a winding path 312 with a corner 312A. The winding path 312 can be connected to the connector SM1 at its one end. The winding path 312 can be in a tortuous shape with at least one twist or turning point, such as the corner 312A. The inclination angle of the corner 312A can be substantially identical to that of the corner 310A. The inclination angle of the corner 312A can be around 135 degrees. The winding path 312 can be separated apart from the winding path 310. In some embodiments, a portion of the top conductive layer 302 is removed to expose the bottom conductive layer 304 to provide a winding path 314 with a corner 314A. The winding path 314 can be connected to the connector SM2 at its one end. The winding path 314 can be in a tortuous shape with at least one twist or turning point, such as the corner 314A. The inclination angle of the corner 314A can be substantially identical to that of the corner 312A. The inclination angle of the corner 314A can be around 135 degrees. The winding path 314 can be separated apart from the winding paths 310 and 312. Forming the winding paths 312 and 314 can include performing one or more lithography, deposition, etching, planarizing, or other suitable processes.

FIG. 4B illustrates a cross-section view of the calibration device 40B along the section line CS1 in FIG. 4A, in accordance with some embodiments of the present disclosure. Six via structures 306 can be formed between the top conductive layer 302 and the bottom conductive layer 304. The top conductive layer 302 can be electrically connected to the bottom conductive layer 304 through the via structures 306. The via structures 306 can be a conductive material, a metal, an alloy, or other combinations thereof.

FIG. 4C illustrates a cross-section view of the calibration device 40C along the section line CS2 in FIG. 4A, in accordance with some embodiments of the present disclosure. The left and right portions of the top conductive layer 302 are removed to form the winding path 310. The winding path 310 can be at the same escalation level as the top conductive layer 302 as shown in FIG. 4C. The winding path 310 can be provided above the bottom conductive layer 304. The top conductive layer 302 can be electrically connected to the bottom conductive layer 304 through two via structures 306.

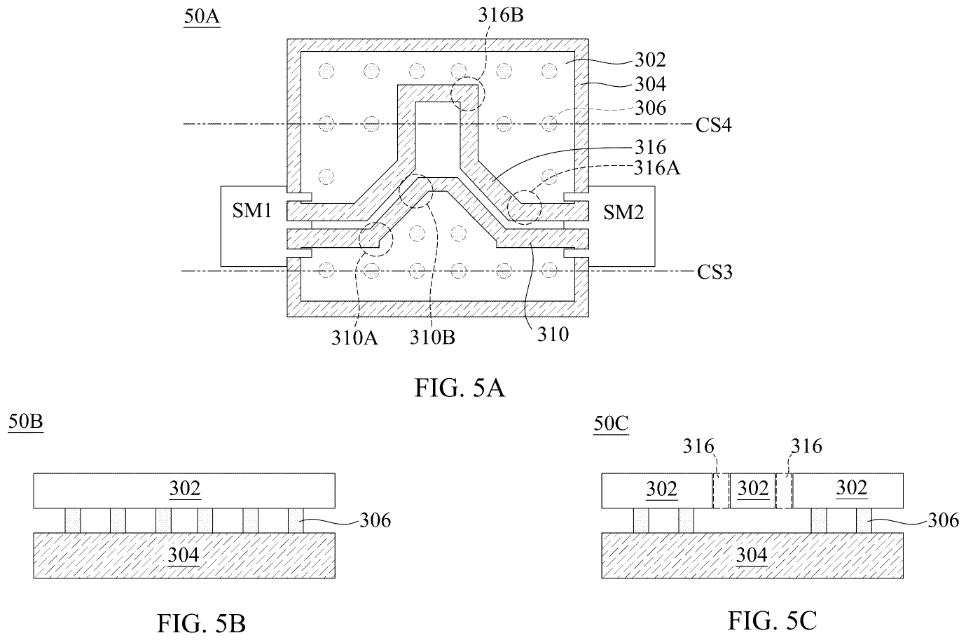

FIG. 5A is a top view of a calibration device 50A, in accordance with some embodiments of the present disclosure. The calibration device 50A of FIG. 5A can be similar to the calibration device 30 of FIG. 2 and FIG. 3, except for the differences described as follows.

The bottom conductive layer 304 can be in a rectangular shape from the top view of the calibration device 50A. The top conductive layer 302 is formed above the bottom conductive layer 304. The top conductive layer 302 can be in a rectangular shape from the top view of the calibration device 50A. In some embodiments, a portion of the top conductive layer 302 is removed to expose the bottom conductive layer 304 to provide a winding path 310 with a plurality of corners 310A and 310B. The winding path 310 can be connected to two connectors SM1 and SM2 at its two ends. The winding path 310 can be in a tortuous shape with several twists or turning points, such as the corners 310A and 310B.

As shown in FIG. 5A, a portion of the top conductive layer 302 is removed to expose the bottom conductive layer 304 to provide a winding path 316 with multiple corners, such as the corners 316A and 316B. The winding path 316 can be connected to the connectors SM1 and SM2 at its two ends. The winding path 316 can be in a tortuous shape with at least one twist or turning point, such as the corners 316A and 316B. The winding path 316 can be separated apart from the winding path 310. Both the winding paths 310 and 316 are continuous patterns. The routing length of the winding path 316 can be greater than the routing length of the winding path 310. The inclination angle of the corner 310A can be substantially identical to that of the corner 310B. The inclination angle of the corners 310A and 310B can be around 135 degrees. The inclination angle of the corner 316A can be greater than that of the corner 316B. The inclination angle of the corner 316A can be around 135 degrees, and the inclination angle of the corner 316B can be around 90 degrees.

FIG. 5B illustrates a cross-section view of the calibration device 50B along the section line CS3 in FIG. 5A, in accordance with some embodiments of the present disclosure. Six via structures 306 can be formed between the top conductive layer 302 and the bottom conductive layer 304. The top conductive layer 302 can be electrically connected to the bottom conductive layer 304 through the via structures 306.

FIG. 5C illustrates a cross-section view 50C of the calibration device along the section line CS4 in FIG. 5A, in accordance with some embodiments of the present disclosure. Two separate portions of the top conductive layer 302 are removed to form the winding path 316. The winding path 316 can be surrounded by the top conductive layer 302. The winding path 316 can be at the same escalation level as the top conductive layer 302 as shown in FIG. 5C. The winding path 316 can be provided above the bottom conductive layer 304. The top conductive layer 302 can be electrically connected to the bottom conductive layer 304 through four via structures 306.

In some embodiments, an open-circuit measurement can be performed utilizing the calibration device 50A of FIG. 5A without being electrically connected to the probe card device. In some embodiments, a short-circuit measurement can be performed utilizing the calibration device 40A of FIG. 4A without being electrically connected to the probe card device. Afterwards, a total frequency response of the calibration device 50A is measured through an electrical connection with the probe card device. Based on the foregoing, various configurations of the calibration devices 40A and 50A can be used to improve the measurement accuracy and simulation result of semiconductor inspection systems in a wider frequency range, including both DC (direct current) and AC (alternating current).

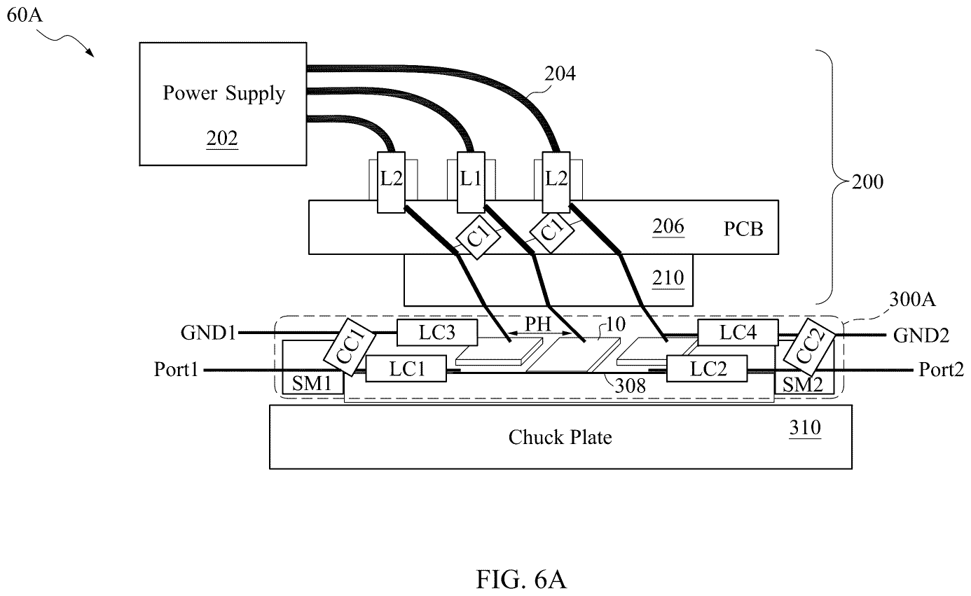

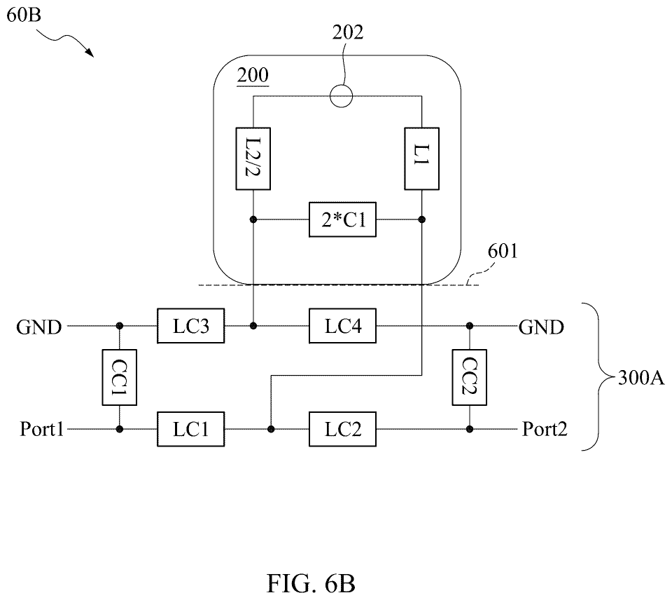

FIG. 6A is a perspective view of the semiconductor inspection system 60A, in accordance with some embodiments of the present disclosure. The semiconductor inspection system 60A of FIG. 6A can be similar to the semiconductor inspection system 30A of FIG. 3 and the semiconductor inspection system 20A FIG. 2, except for the differences described as follows.

The probe card device 200 can include parasitic inductors L1 and L2 and parasitic capacitors C1 in order to simulate or evaluate the electrical property and frequency response of the probe card device 200. As shown in FIG. 6A, the parasitic inductor L1 can correspond to the power pin P1 of FIG. 3, and the two parasitic inductors L2 can correspond to the two ground pins G1 and G2 of FIG. 3. Two parasitic capacitors C1 are illustrated between and correspond to the needles 208. Furthermore, the distance between two adjacent ones of the needles 208 can be defined as a pitch PH of the semiconductor inspection system 60A. The pitch PH can be increased or decreased to achieve a high measurement accuracy by utilizing the calibration device 300A on the PCB 308.

The calibration device 300A can further include two ground ports GND1 and GND2, and two signal ports Port1 and Port2 for receiving and transmitting electrical signals with the probe card device 200 and the testing device 400. The signal port Port1 and the ground port GND1 are arranged on one side of the calibration device 300A close to the connector SM1. The signal port Port2 and the ground port GND2 are arranged on another side of the calibration device 300A close to the connector SM2, which is opposite to the side of the connector SM1.

The calibration device 300 can include four parasitic inductors LC1, LC2, LC3, LC4, and two parasitic capacitors CC1 and CC2 in order to simulate or evaluate the electrical property and frequency response of the calibration device 300. The parasitic capacitor CC1 and parasitic inductors LC1 and LC3 can be arranged between the semiconductor device 10 and the connector SM1. The parasitic capacitor CC1 can be electrically connected between the parasitic inductors LC1 and LC3. The parasitic inductor LC3 can be electrically connected to the ground port GND1, and the parasitic inductor LC1 can be electrically connected to the signal port Port1. The parasitic capacitor CC2 and parasitic inductors LC2 and LC4 can be arranged between the semiconductor device 10 and the connector SM2. The parasitic capacitor CC2 can be electrically connected between the parasitic inductors LC2 and LC4. The parasitic inductor LC4 can be electrically connected to the ground port GND2, and the parasitic inductor LC2 can be electrically connected to the signal port Port2.

FIG. 6B is a circuit diagram 60B corresponding to the semiconductor inspection system 60A of FIG. 6A, in accordance with some embodiments of the present disclosure. The probe card device 200 can include a parasitic capacitor 2*C1, and parasitic inductors L1 and L2/2. The parasitic capacitor 2*C1 of FIG. 6B can correspond to the two parasitic capacitors C1 of FIG. 6A. The parasitic inductor L2/2 of FIG. 6B can correspond to the two parasitic inductors L2 of FIG. 6A. The probe card device 200 and the calibration device 300A can be electrically connected through the probe interface 601. The calibration device 300A can be used for impedance matching with the parasitic impedance of the probe card device 200, so as to improve the measurement accuracy and reliability of the probe card device 200. In addition, the parasitic impedance of the probe card device 200 can be used to improve or optimize a probe card model of the probe card device 200 for simulation.

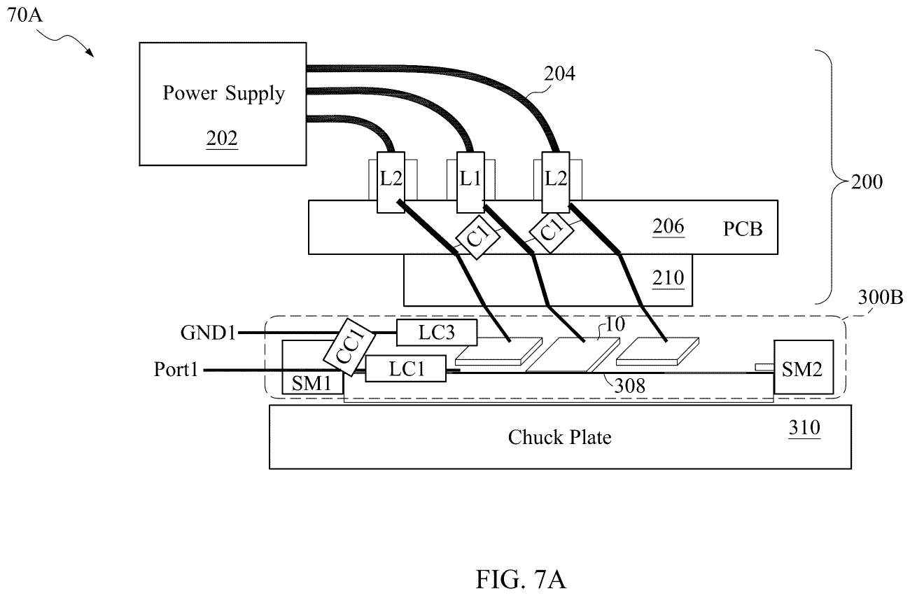

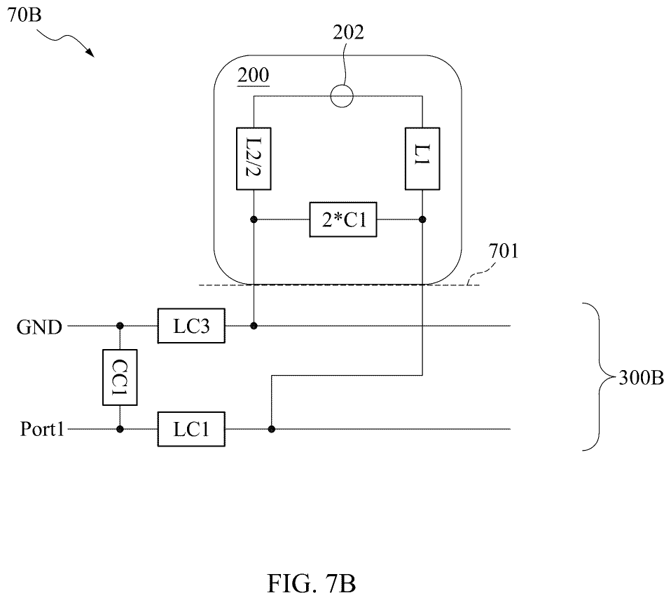

FIG. 7A is a perspective view of the semiconductor inspection system 70A, in accordance with some embodiments of the present disclosure. The semiconductor inspection system 70A of FIG. 7A can be similar to the semiconductor inspection system 30A of FIG. 3 and the semiconductor inspection system 20A FIG. 2, except for the differences described as follows.

The probe card device 200 can include parasitic inductors L1 and L2 and parasitic capacitors C1 in order to simulate or evaluate the electrical property and frequency response of the probe card device 200. The calibration device 300A can include a ground port GND1 and a signal port Port1 for receiving and transmitting electrical signals with the probe card device 200 and the testing device 400. The signal port Port1 and the ground port GND1 are arranged on one side of the calibration device 300B close to the connector SM1. Compared to the semiconductor inspection system 60A of FIG. 6A, the connector SM2 can be directly connected to the semiconductor device 10 without passing through any parasitic inductors or parasitic capacitors. In addition, there is no ground port or signal port near the connector SM2.

FIG. 7B is a circuit diagram 70B corresponding to the semiconductor inspection system of FIG. 7A, in accordance with some embodiments of the present disclosure. The probe card device 200 can include a parasitic capacitor 2*C1, and two parasitic inductors L1 and L2/2. The parasitic capacitor 2*C1 of FIG. 7B can correspond to the two parasitic capacitors C1 of FIG. 7A. The parasitic inductor L2/2 of FIG. 7B can correspond to the two parasitic inductors L2 of FIG. 7A. The probe card device 200 and the calibration device 300B can be electrically connected through the probe interface 701. The calibration device 300B can be used for impedance matching with the parasitic impedance of the probe card device 200, so as to improve the measurement accuracy and reliability of the probe card device 200.

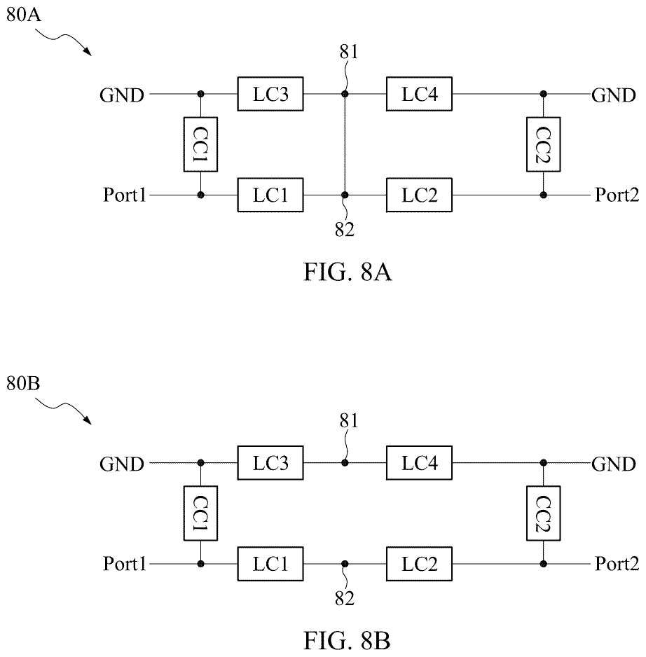

FIG. 8A is a circuit diagram corresponding to the calibration device 80A, in accordance with some embodiments of the present disclosure. The calibration device 80A of FIG. 8A can correspond to the calibration device 40A of FIG. 4A for short-circuit testing. The calibration device 80A can include four parasitic inductors LC1, LC2, LC3, LC4, and two parasitic capacitors CC1 and CC2. As shown in FIG. 8A, the parasitic inductors LC3 and LC4 are electrically connected to the node 81, and the parasitic inductors LC1 and LC2 are electrically connected to the node 82. In some embodiments, the nodes 81 and 82 are electrically connected as a short circuit therebetween for performing the short-circuit testing.

FIG. 8B is another circuit diagram corresponding to the calibration device, in accordance with some embodiments of the present disclosure. The calibration device 80B of FIG. 8B can correspond to the calibration device 50A of FIG. 5A for open-circuit testing. The calibration device 80B can include four parasitic inductors LC1, LC2, LC3, LC4, and two parasitic capacitors CC1 and CC2. As shown in FIG. 8B, the parasitic inductors LC3 and LC4 are electrically connected to the node 81, and the parasitic inductors LC1 and LC2 are electrically connected to the node 82. In some embodiments, the nodes 81 and 82 are electrically disconnected as an open circuit therebetween for performing the open-circuit testing.

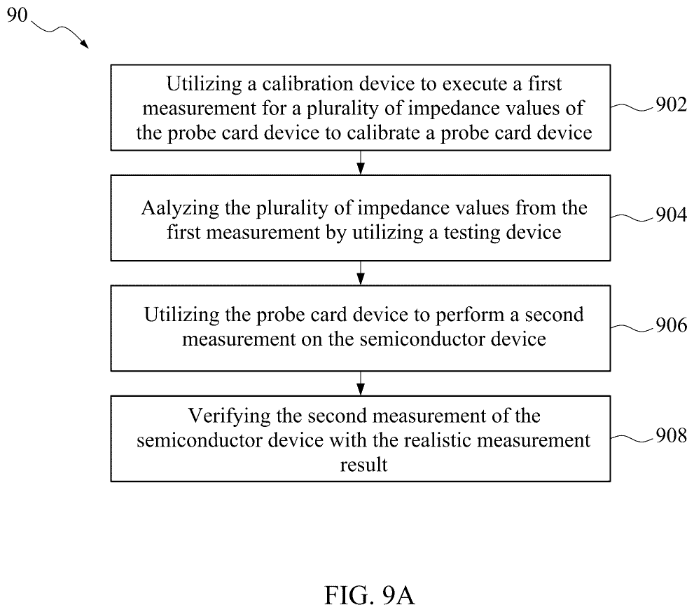

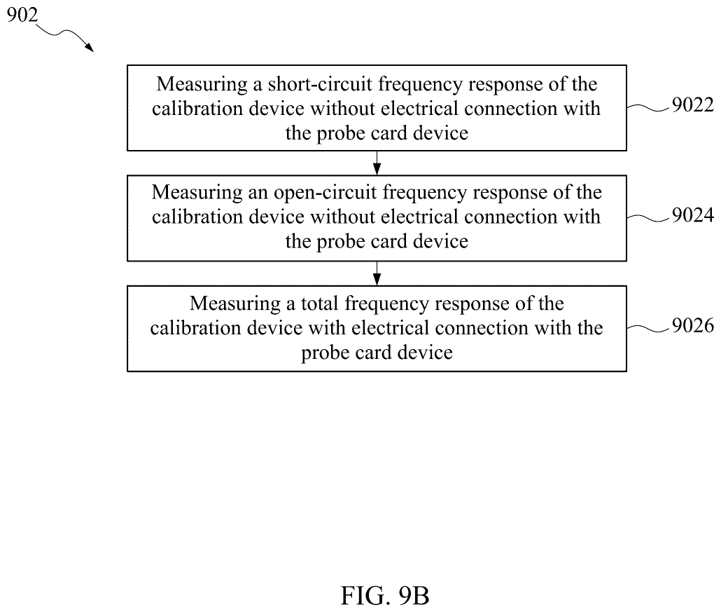

FIG. 9A illustrates a flow chart 90 including calibration methods for operating the semiconductor inspection system, in accordance with some embodiments of the present disclosure. In operation 902, a calibration device is utilized to execute a first measurement to obtain a plurality of impedance values of the probe card device in order to calibrate a probe card device. Specifically, the impedance values can include at least one parasitic inductance value and at least one parasitic capacitance value of the probe card device. For example, the first measurement can be executed by the calibration device 300A of FIG. 6A to obtain the impedance values of the parasitic inductors L1 and L2 and parasitic capacitors C1 of the probe card device 200. In operation 904, the plurality of impedance values from the first measurement are analyzed by utilizing a testing device, to increase the measurement accuracy of the probe card device. In operation 906, the probe card device is utilized to perform a second measurement on the semiconductor device. For example, the second measurement can be executed by the probe card device 200 of FIG. 6A to measure the semiconductor device 10. That is, the second measurement is executed after the first measurement. Because the probe card device 200 is calibrated or corrected by the calibration device 300A during the first measurement in operation 902, the second measurement performed by the probe card device 200 on the semiconductor device 10 can thus be improved to provide better frequency response and measurement accuracy. In operation 908, the second measurement of the semiconductor device is verified with the realistic measurement result. The realistic measurement result can refer to the measurement performed on the benchmark device 20 as shown in FIG. 1B, in order to evaluate and verify whether the probe card device can provide an accurate and reliable measurement.

FIG. 9B illustrates another flow chart including calibration methods for operating the semiconductor inspection system, in accordance with some embodiments of the present disclosure. The operation 902 in FIG. 9A can further include three operations 9022, 9024, and 9026 as shown in FIG. 9B. In operation 9022, a short-circuit frequency response of the calibration device is measured without an electrical connection to the probe card device. For example, the short-circuit measurement can be executed by utilizing the calibration device 40A of FIG. 4A and the calibration device 80A of FIG. 8A to obtain the short-circuit frequency response. The short-circuit measurement can be performed utilizing the calibration device without being electrically connected to the probe card device.

In operation 9024, an open-circuit frequency response of the calibration device is measured without an electrical connection to the probe card device. For example, the open-circuit measurement can be executed by utilizing the calibration device 50A of FIG. 5A and the calibration device 80B of FIG. 8B to obtain the open-circuit frequency response. The open-circuit measurement can be performed utilizing the calibration device without being electrically connected to the probe card device. In operation 9026, a total frequency response of the calibration device is measured with electrical connection with the probe card device. For example, the total frequency measurement can be executed by utilizing the calibration device 50A of FIG. 5A and the calibration device 80B of FIG. 8B to obtain the open-circuit frequency response. The total frequency measurement can be performed utilizing the calibration device which is electrically connected to the probe card device. The present disclosure provides various measurement methods in association with the corresponding calibration devices to improve the measurement accuracy of semiconductor inspection system, by analyzing the parasitic impedance within the probe card device through the proposed calibration device, so as to enhance the measurement accuracy especially in high frequency response.

While disclosed methods (e.g., flowchart 90) are illustrated and described below as a series of acts or events, it will be appreciated that the illustrated ordering of such acts or events are not to be interpreted in a limiting sense. For example, some operations may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

Some embodiments of the present disclosure provide a semiconductor inspection system. The semiconductor inspection system comprises a probe card device, a calibration device and a testing device. The probe card device is configured to perform a first measurement on a semiconductor device. The probe card device is disposed on a first PCB. The calibration device is electrically connected to the probe card device and is configured to execute a second measurement to obtain a plurality of impedance values of the probe card device in order to calibrate the probe card device. The calibration device is disposed on a second PCB different from the first PCB. The second PCB is provided on a chuck plate, and the second measurement is executed before the first measurement. The testing device is electrically connected to the calibration device and is configured to analyze the plurality of impedance values of the second measurement.

Some embodiments of the present disclosure provide a semiconductor inspection system. The semiconductor inspection system comprises a probe card device and a calibration device. The probe card device is configured to perform a first measurement on a semiconductor device. The probe card device is disposed on a first PCB. The calibration device is electrically connected to the probe card device, and configured to execute a second measurement to obtain a plurality of impedance values of the probe card device in order to calibrate the probe card device. The calibration device is disposed on a second PCB different from the first PCB. The calibration device includes a first connector, a second connector, a bottom conductive layer and a top conductive layer. The second connector is electrically connected to the first connector. The bottom conductive layer is electrically connected between the first connector and the second connector, and configured in a first rectangular shape from a top view of the calibration device. The top conductive layer is formed above the bottom conductive layer and electrically connected between the first connector and the second connector. The top conductive layer is configured in a second rectangular shape from the top view, the second rectangular shape is formed within the first rectangular shape from the top view, and a portion of the top conductive layer is removed to expose the bottom conductive layer to provide a first winding path with a plurality of first corners.

Some embodiments of the present disclosure provide a calibration method for operating a semiconductor inspection system. The calibration method includes utilizing a calibration device to execute a first measurement to obtain a plurality of impedance values of the probe card device to calibrate a probe card device; analyzing the plurality of impedance values from the first measurement by utilizing a testing device; and utilizing the probe card device to perform a second measurement on a semiconductor device.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor inspection system, comprising:
a probe card device, configured to perform a first measurement on a semiconductor device, wherein the probe card device is disposed on a first printed circuit board (PCB);
a calibration device electrically connected to the probe card device, and configured to execute a second measurement to obtain a plurality of impedance values of the probe card device in order to calibrate the probe card device, wherein the calibration device is disposed on a second PCB different from the first PCB, the second PCB is provided on a chuck plate, and the second measurement is executed before the first measurement; and
a testing device electrically connected to the calibration device, and configured to analyze the plurality of impedance values of the second measurement.

2. The semiconductor inspection system of claim 1, wherein the plurality of impedance values comprise at least one parasitic inductance value and at least one parasitic capacitance value of the probe card device.

3. The semiconductor inspection system of claim 1, wherein the probe card device further comprises:
a power supply, providing power to the probe card device;
a first cable, electrically connected between the power supply and the first PCB; and
a plurality of first needles, electrically connected to the power supply, wherein the plurality of first needles are configured to be in direct contact with the semiconductor device to perform the first measurement.

4. The semiconductor inspection system of claim 3, wherein the probe card device further comprises:
at least one power pin, electrically connected to the first needles to transmit power from the power supply to the semiconductor device; and
at least one ground pin, electrically connected to the first needles to serve as a ground of the semiconductor inspection system.

5. The semiconductor inspection system of claim 4, wherein when the calibration device is arranged in a first configuration, the calibration device further comprises a first signal port and a first ground port arranged on a side of the calibration device.

6. The semiconductor inspection system of claim 4, wherein when the calibration device is arranged in a second configuration, the calibration device further comprises a first signal port, a second signal port, a first ground port and a second ground port, the first signal port and the first ground port are arranged on a first side of the calibration device, and the second signal port and the second ground port are arranged on a second side of the calibration device opposite to the first side.

7. The semiconductor inspection system of claim 1, wherein the calibration device further comprises:
a bottom conductive layer;
a top conductive layer, formed above the bottom conductive layer; and
a plurality of via structures, formed between the top conductive layer and the bottom conductive layer.

8. The semiconductor inspection system of claim 7, wherein the calibration device further comprises two connectors for electrically connecting the calibration device to the testing device, wherein the two connectors are provided on opposite ends of the calibration device.

9. A semiconductor inspection system, comprising:
a probe card device, configured to perform a first measurement on a semiconductor device, wherein the probe card device is disposed on a first printed circuit board (PCB); and
a calibration device electrically connected to the probe card device, and configured to execute a second measurement to obtain a plurality of impedance values of the probe card device in order to calibrate the probe card, wherein the calibration device is disposed on a second PCB different from the first PCB, and the calibration device comprises:
a first connector;
a second connector, electrically connected to the first connector;
a bottom conductive layer, electrically connected between the first connector and the second connector, and configured in a first rectangular shape from a top view of the calibration device; and
a top conductive layer, formed above the bottom conductive layer and electrically connected between the first connector and the second connector, wherein the top conductive layer is configured in a second rectangular shape from the top view, the second rectangular shape is formed within the first rectangular shape from the top view, and a portion of the top conductive layer is removed to expose the bottom conductive layer to provide a first winding path with a plurality of first corners.

10. The semiconductor inspection system of claim 9, wherein the second measurement is executed before the first measurement.

11. The semiconductor inspection system of claim 9, wherein the first winding path is formed between the first connector and the second connector.

12. The semiconductor inspection system of claim 11, wherein another portion of the top conductive layer is removed to expose the bottom conductive layer to provide a second winding path with a second corner and a third winding path with a third corner, the second winding path is in contact with the first connector, the third winding path is in contact with the second connector, and the second winding path and the third winding path are not in contact with each other.

13. The semiconductor inspection system of claim 12, wherein the first winding path, the second winding path and the third winding path are used to measure a short-circuit frequency response of the calibration device.

14. The semiconductor inspection system of claim 11, wherein another portion of the top conductive layer is removed to expose the bottom conductive layer to provide a fourth winding path with a plurality of fourth corners, the fourth winding path is formed between the first connector and the second connector, and a length of the fourth winding path is greater than a length of the first winding path.

15. The semiconductor inspection system of claim 14, wherein the first winding path and the fourth winding path are used to measure an open-circuit frequency response of the calibration device.

16. The semiconductor inspection system of claim 13, wherein the short-circuit frequency response and the open-circuit frequency response are measured by disconnecting the probe card device.

17. The semiconductor inspection system of claim 16, wherein the first winding path and the fourth winding path are used to measure a total frequency response of the calibration device by electrically connecting to the probe card device.

18. A calibration method for operating a semiconductor inspection system, comprising:
utilizing a calibration device to execute a first measurement to obtain a plurality of impedance values of the probe card device to calibrate a probe card device;
analyzing the plurality of impedance values from the first measurement by utilizing a testing device; and
utilizing the probe card device to perform a second measurement on a semiconductor device.

19. The calibration method of claim 18, further comprising:
measuring a short-circuit frequency response of the calibration device without electrical connection with the probe card device; and
measuring an open-circuit frequency response of the calibration device without electrical connection with the probe card device.

20. The calibration method of claim 19, further comprising:
measuring a total frequency response of the calibration device with electrical connection with the probe card device.
